(19) United States
(12) Patent Application Publication
(10) Pub. No.: US 2025/0103087 A1
(43) Pub. Date: Mar. 27, 2025

(54) CIRCUIT FOR SUPPLYING A CLOCK SIGNAL

(71) Applicant: STMICROELECTRONICS INTERNATIONAL N.V., Geneva (CH)

(72) Inventors: Thomas JOUANNEAU, ST-EGREVE (FR); Lea Sandrina Frédérique ENGINGER, Grenoble (FR)

(21) Appl. No.: 18/884,579

(22) Filed: Sep. 13, 2024

(30) Foreign Application Priority Data
Sep. 27, 2023 (FR) 2310260

(51) Int. Cl. G06F 1/04; H03K 5/135

(52) U.S. Cl. CPC G06F 1/04; H03K 5/135

(57) ABSTRACT

The present disclosure provides a circuit for supplying a clock signal. An example circuit for supplying a clock signal comprises a selector of one signal out of a plurality of clock signals; a switch between the selector and a node for outputting the selected clock signal, the circuit being configured so that the application of a control signal for selecting one of the clock signals causes, in the order, the turning off of the switch, the selection of the signal via the selector, and the turning on of the switch.

### CROSS REFERENCE TO RELATED APPLICATION(S)

This application claims the priority benefit of French patent application number FR2310260, filed on Sep. 27, 2023, entitled “Circuit de fourniture d'un signal d'horloge,” which is hereby incorporated by reference to the maximum extent allowable by law.

### TECHNICAL FIELD

The present disclosure generally concerns circuits for supplying a clock signal, and the associated methods.

### BACKGROUND

Most digital circuits use a plurality of clock signals for controlling the synchronicity of their operations. In the use of these circuits, the selection and the passing from one clock signal to another requires specific attention at the risk of generating glitches. Current solutions for clock signal selection are energy and chip surface area intensive.

### BRIEF SUMMARY

There exists a need to limit the creation of glitches during the selection of a clock signal while limiting the power consumption and the necessary chip surface area.

An embodiment overcomes all or part of the disadvantages of known electronic circuits.

An embodiment provides a circuit for supplying a clock signal comprising:
a selector of one signal out of a plurality of clock signals;
a switch between the selector and a node for outputting the selected clock signal,
the circuit being configured so that the application of a control signal for selecting one of the clock signals causes, in the order, the turning off of the switch, the selection of the signal via the selector, and turning on of the switch.

An embodiment provides a method of operation of a circuit for supplying a clock signal, the method comprising, as a result of the application of a control signal for selecting a signal, the following successive steps:
the turning off of a switch coupling a selector of one clock signal out of a plurality and an output node;
the selection of the signal via the selector and;
the turning on of the switch.

In an embodiment, the circuit is configured to turn off switch when a change in the selection control signal is detected.

In an embodiment, the circuit is configured to select the signal after a first delay, of at least two rising edges of a shift signal, following the detection of the change.

In an embodiment, the circuit is configured to turn on the switch after a second delay, of at least two rising edges of the shift signal, following the selection.

In an embodiment, the electronic circuit is configured to generate, with a first circuit, a first signal when the change is detected.

In an embodiment, the circuit is configured to generate, with a second circuit, a second signal, originating from the first signal, and shifted in time by the first delay.

In an embodiment, the second circuit comprises an SR-type latch having an output coupled to an inverter which is in series with an input of a shift register comprising at least two stages and/or a delay cell;
the second signal being generated on an output of the shift register;
a first input of the SR-type latch being configured to receive the first signal and a second input of the SR-type latch being configured to receive the second signal.

In an embodiment, the circuit comprises a third circuit configured to authorize the propagation of the selection control signal to the signal selector according to an output of a first logic block capable of performing a NOR function based on a signal present at the output of the inverter and on the second signal.

In an embodiment, the third circuit comprises one latch per control signal forming the selection control signal, each latch having:
a gate input coupled to the output of the first logic block,
a data input configured to receive the corresponding control signal, and
an output coupled to the signal selector.

In an embodiment, the shift signal is a clock signal having a frequency smaller than or equal to that of the signal, among the plurality of clock signals, having the smallest frequency.

In an embodiment, the switch comprises a first block having:
a clock input coupled to the selector,
a first enable input coupled to the output of the first logic block, and
an output coupled to a second enable input of a second block of the switch; and
an output of the second block of the switch being coupled to the output node and a clock input of the second block being coupled to an output of the selector.

In an embodiment, the switch is configured to be off when the output of the first logic block is at a low level.

In an embodiment, the switch is configured to be on when the output of the first logic block is at a high level, the selected clock signal then being on the output node.

In an embodiment, the first block of the switch comprises a first and a second flip-flops in series, the clock input of the first block being a clock input of the first flip-flop and the output of the second flip-flop being coupled to the second enable input of the second block.

An embodiment provides a microcontroller comprising a circuit for supplying a clock signal such as described hereabove.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows a simplified view of an example of an electronic circuit;

FIG. 2 very schematically shows an example of implementation of a block of the electronic circuit of FIG. 1;

FIG. 3 very schematically shows a block of the electronic circuit of FIG. 1 according to an embodiment;

FIG. 4 shows a circuit of the block of FIG. 3 according to an embodiment;

FIG. 5 shows a circuit of the block of FIG. 3 according to an embodiment;

FIG. 6 shows a circuit of the block of FIG. 3 according to an embodiment;

FIG. 7 shows a circuit of the block of FIG. 3 according to an embodiment; and

FIG. 8 is a timing diagram of the operation of the block of FIG. 3.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

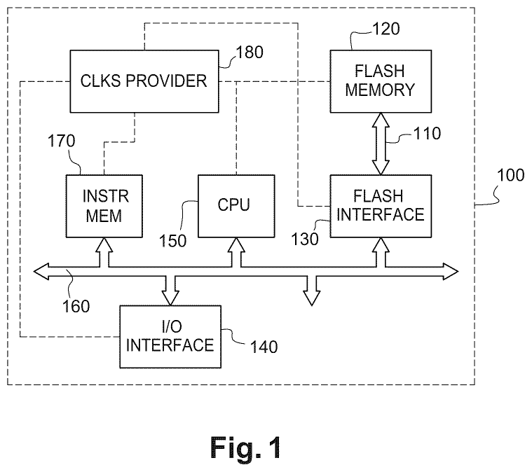

FIG. 1 shows a simplified view of an example of an electronic circuit 100.

Circuit 100 comprises a memory 120 (FLASH MEMORY) for example non-volatile, or of FLASH memory type, capable of communicating, via a communication bus 110, with for example a memory interface 130 (FLASH INTERFACE) configured to write or read data into and from non-volatile memory 120.

Circuit 100 further comprises, for example, a processing unit 150 (CPU) comprising one or a plurality of processors under control of instructions stored in an instruction memory 170 (INSTR MEM). Instruction memory 170 is for example a volatile memory of random access memory (RAM) type. Processing unit 150 and memory 170 communicate, for example, via a system (data, address, and control) bus 160. Memory 120 is coupled to system bus 160 via non-volatile memory interface 130 and via bus 110. Device 100 further comprises for example an input/output interface 140 (I/O interface) coupled to system bus 160 to communicate with the outside.

Circuit 100 may integrate other circuits implementing other functions (for example, one or a plurality of volatile and/or non-volatile memories, other processing units), not illustrated in FIG. 1. Among these other circuits, circuit 100 for example comprises a read-only or static memory.

Some or all of the different elements 110, 120, 130, 140, 150, 160, 170 may have a digital operation. In this case, the clocking of their operations is for example obtained by using one or a plurality of clock signals forming a pulse sequence, for example in the form of square pulses, alternating between a high state (1) and a low state (0).

Circuit 100 comprises a block 180 (CLKS PROVIDER) for supplying one or a plurality of clock signals. This supply block is for example coupled, preferably connected, to one of or all the elements 110, 120, 130, 140, 150, 160, 170.

Supply block 180 may have to change the clock signal, for example with a signal at higher or lower frequency, that it supplies to the elements to which it is connected. This change is for example performed by selecting one among a plurality of clock signals made available by clock signal generation circuits, not shown.

The selection of one clock signal out of a plurality requires specific attention since, if the clock signal to be changed is interrupted at the wrong time, for example in the high state, or during the switching from one clock signal to the other, this may generate glitches.

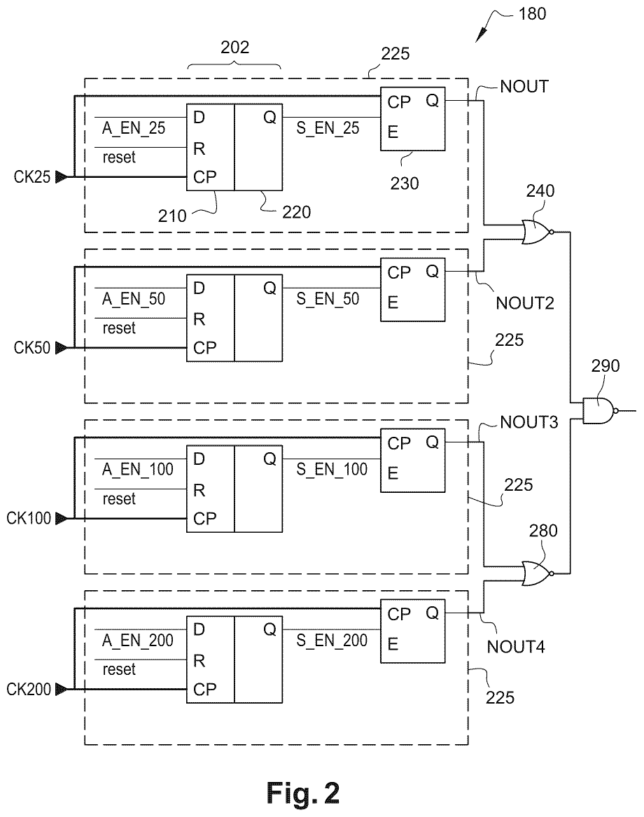

FIG. 2 very schematically shows an example of implementation of a block of the electronic circuit of FIG. 1. More particularly, FIG. 2 illustrates an example of implementation of supply block 180.

The example of FIG. 2 comprises a first, a second, a third, and a fourth switch circuits 225, for example similar to one another.

Each of switches 225 for example comprises a first block 202 forming a reclocking cell. First block 202 for example comprises a first and a second flip-flop 210, 220, for example D flip-flops, in series. In an example, these flip-flops form a shift register. In another example, the two flip-flops 210 and 220 are of rising edge detection type. First flip-flop 210 comprises a clock input CP, a reset input R, and a so-called enable input D. An output of first flip-flop 210 is coupled to the input of second flip-flop 220. The clock CP and reset R inputs of the first flip-flop 210 of switches 225 respectively correspond to a clock input CP and to a reset input R of the respective switches 225.

The clock input CP of each switch 225 is configured to be coupled to a rail receiving a clock signal C25, CK50, CK100, CK200, having a different frequency or duty cycle from one switch 225 to the other. In an example, a signal CK25 has a frequency for example of 25 MHz, signal CK50 has a frequency double that of signal CK25, signal CK100 has a frequency double that of signal CK50, and signal CK200 has a frequency double that of signal CK100. The D input of each of the first flip-flops 210 of each switch 225 is configured to receive a respective enable signal A_EN_25, A_EN_50, A_EN_100, A_EN_200. The D input of each first flip-flop 210 corresponds to an enable input D of the respective switch 225.

In the shown example, each switch 225 further comprises a second block 230. A Q output of the second flip-flop 220 of each switch 225 is coupled to an enable input E of the second block 230 of the respective switch 225. The respective enable input E of each second block 230 is configured to receive an enable signal S_EN_25, S_EN_50, S_EN_100, S_EN_200, which corresponds to the output signal on the Q output of the second flip-flop 220 of the corresponding first block 202. Generally, there is called S_EN_CK the respective enable signal corresponds to the output signal on the Q output of the second flip-flop 220 of first block 202 corresponding to a clock signal CK. In an example, the second blocks 230 are formed with a D flip-flop.

Second blocs 230 further comprise a clock input CP coupled to the first corresponding rail receiving one of clock signals CK25, CK50, CK100, CK200. A Q output of second block 230 is coupled to an output node NOUT, NOUT2, NOUT3, and NOUT4 of the corresponding switch 225.

Switches 225, via second block 230, act as clock gating cells by stopping propagating the clock signal to the respective output nodes NOUT, NOUT2, NOUT3, NOUT4 only when the clock signal is in the low state to avoid glitches and provided for the enable signal of second block 230 to be synchronous with the clock signal to be stopped or to be propagated. First block 202 enables the enable signal of second block 230 to be synchronous with the clock signal to be stopped or to be propagated.

In operation, switches 225 may be in an off state or in an on state. In a so-called on state, switches 225 allow the propagation of the received clock signal on their clock input CP, in other words the clock input common to first flip-flop 210 and to the second block, to their respective output nodes NOUT, NOUT2, NOUT3, NOUT4. In a so-called off state, switches 225 no longer allow the propagation of the clock signal to the respective output node NOUT, NOUT2, NOUT3, NOUT4.

In the following examples of operation, both flip-flops 210 and 220 are of rising edge detection type.

As concerns switches 225, to switch from the off mode to the on mode, the respective enable signal A_EN_25, A_EN_50, A_EN_100, A_EN_200 of the first block is in the low state, as well as the enable signal S_EN_25, S_EN_50, S_EN_100, S_EN_200 of second block 230 and the signal on the respective output node NOUT, NOUT2, NOUT3, NOUT4 is in the low state. Then, the respective enable signal A_EN_25, A_EN_50, A_EN_100, A_EN_200 of the first block rises to the high state. Then, the enable signal S_EN_25, S_EN_50, S_EN_100, S_EN_200 of the second block 230 also rises to the high state after two rising edges (corresponding to the number of flip-flops 210, 220 present) received on the clock input. The clock signal propagates on the corresponding output node after a third rising edge received on the clock input.

To switch from the on mode to the off mode, the respective enable signal A_EN_25, A_EN_50, A_EN_100, A_EN_200 of the first block is in the high state, as well as the enable signal S_EN_25, S_EN_50, S_EN_100, S_EN_200 of the second block 230. In the on mode, the signal which propagates on the respective output node NOUT, NOUT2, NOUT3, NOUT4 is the clock signal received on the clock input. Then, the respective enable signal A_EN_25, A_EN_50, A_EN_100, A_EN_200 of the first block falls back to the low state. Then, the enable signal S_EN_25, S_EN_50, S_EN_100, S_EN_200 of second block 230 falls back in turn to the low state after two rising edges (corresponding to the number of flip-flops 210, 220 present) received on the clock input. The clock signal then no longer propagates on the corresponding output node after a third rising edge received on the clock input.

In the shown example, supply block 180 comprises two logic blocks 240, 280 configured to perform a NOR-type function respectively based on the signals present on nodes NOUT, NOUT2 and NOUT3, NOUT4.

In the shown example, supply block 180 further comprises a logic block 290 configured to perform a NAND-type function based on the signals respectively present at the output of logic blocks 240 and 280.

According to the state of the respective enable signals A_EN_25, A_EN_50, A_EN_100, A_EN_200 of each of switches 225, supply block 180 allows the selection, at the output of logic block 290, of a clock signal from among the possible signals CK25, CK50, CK100, and CK200.

The fact for the circuit of FIG. 2 to require as many switches 225 as clock signals to be selected implies a high chip surface area and energy consumption. In the case of microcontrollers, for example, these two factors are critical and it would be appropriate to limit them while keeping the glitch filtering capacity.

For this purpose, the described embodiments provide a circuit for supplying a clock signal comprising:
a selector of one signal out of a plurality of clock signals;
a switch between the selector and a node for supplying the selected clock signal,
the electronic circuit being configured so that the application of a control signal for selecting one of the clock signals causes, in the order, the turning off of the switch, the selection of the signal via the selector, and the turning on of the switch.

The fact of having a single switch for all the available clock signals enables to gain chip surface area and also to lower the power consumption. The fact for the switch to be first off before the selection of the clock signal to be supplied enables not to propagate glitches which might be generated at the time of the selection of the clock signal. Once the new clock signal has been selected, and thus stabilized, it is then possible to turn on the switch to propagate the selected clock signal.

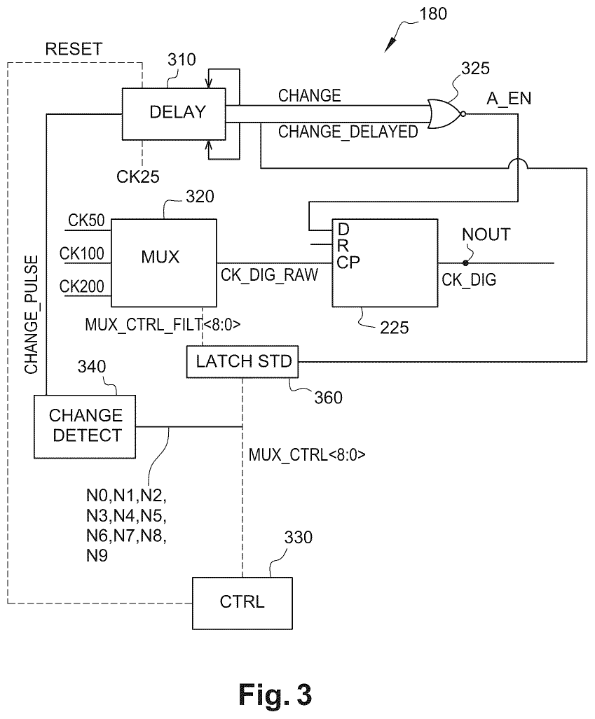

FIG. 3 very schematically shows a block of the electronic circuit 100 of FIG. 1 according to an embodiment.

More precisely, FIG. 3 illustrates an embodiment of supply block 180.

In the example of FIG. 3, supply block 180 comprises a selector 320 (MUX) having an output coupled to a switch, for example similar to the switch 225 of FIG. 2, so that a signal (CK_DIG_RAW) present at the output of selector 320 is also present at the clock input CP of switch 225.

In the shown example, selector 320 is configured to select one among clock signals CK50, CK100, CK200, as well as six other signals, not shown, based on control signals (MUX_CTRL_FILT<8:0>). Notation <8:0> is a notation concatenated for nine different signals and designated with references 0 to 8. Control signals MUX_CTRL_FILT<8:0> originate from a control unit 330 (CTRL) which generates raw selection control signals (MUX_CTRL<8:0>). The propagation of these raw selection control signals MUX_CTRL<8:0> to selector 320 is controlled by a latch circuit 360 (LATCH STD) according to the state of a signal (CHANGE_DELAYED).

In the shown example, supply block 180 comprises a circuit 340 (CHANGE DETECT) configured to detect a change in the raw selection control signals MUX_CTRL<8:0>. When a change is detected, a signal (CHANGE_PULSE) for example takes the form of a pulse.

Circuit 340 is coupled, preferably connected, to a circuit 310 (DELAY) configured to generate a signal (CHANGE_DELAYED), according to signal CHANGE_PULSE, and shifted in time by a first time shift.

Circuit 310 receives as an input a clock signal CK25 which for example has a frequency twice smaller than the slowest signal of the available clock signals (here CK50) or a clock signal having a frequency smaller, for example by half, than the slowest clock signal. Circuit 310 is further configured to receive as an input a reset signal RESET sent by control unit 330.

Circuit 310 is configured to deliver as an output a signal (CHANGE) and a signal (CHANGE_DELAYED). Signals CHANGE and CHANGE_DELAYED are looped back in circuit 310 so that signal CHANGE rises when a positive pulse is present on signal CHANGE_PULSE, and it falls when signal CHANGE_DELAYED rises. Signal CHANGE_DELAYED corresponds to the image of signal CHANGE with a time shift of at least two, preferably at least three, rising edges of the clock signal CK25 which is at the input of circuit 310.

In the shown example, the D input of switch 225 is coupled, preferably connected, to circuit 310 via a logic block 325 configured to perform a NOR-type function based on signals CHANGE and CHANGE_DELAYED. The output of logic block 325 is an enable signal A_EN of the first block 202 of switch 225.

A method of operation of the supply circuit 180 of FIG. 3 comprises, as a result of the application of a signal selection control signal, the following successive steps:
the turning off of the switch 225 coupling the selector 320 of a clock signal among a plurality and output node NOUT;
the selection of the signal via selector 320 and;
the turning on of switch 225.

In operation, circuit 340 is configured to turn off switch 225 when one or a plurality of changes occur in signals MUX_CTRL<8:0>, which generates a pulse on signal CHANGE_PULSE. Circuit 310 receives pulse CHANGE_PULSE, which lowers at its output signal CHANGE, which switches to the low state signal A_EN, which in fine turns off switch 225.

Signal CHANGE is looped back in circuit 310 and becomes signal CHANGE_DELAYED after at least two clock pulses of clock signal CK25, having a frequency twice smaller than the slowest selectable signal, here CK50. Signal CHANGE_DELAYED then is in the high state, which triggers the locking of signals MUX_CTRL<8:0> by circuit 360 so that they propagate to the selector. The selected clock signal is then delivered on the clock input CP of switch 225, which is still off at this stage.

Signal CHANGE_DELAYED is also looped back in circuit 310 and the rising edge of signal CHANGE_DELAYED resets signal CHANGE to the low state.

The low state of signal CHANGE then propagates to become signal CHANGE_DELAYED after at least two rising edges of clock signal CK25. Signals CHANGE and CHANGE_DELAYED being in the low state, signal A_EN switches to the high state, which turns on switch 225 and enables to propagate, on the output node NOUT of switch 225, a signal CK_DIG which is the new clock signal which has been selected.

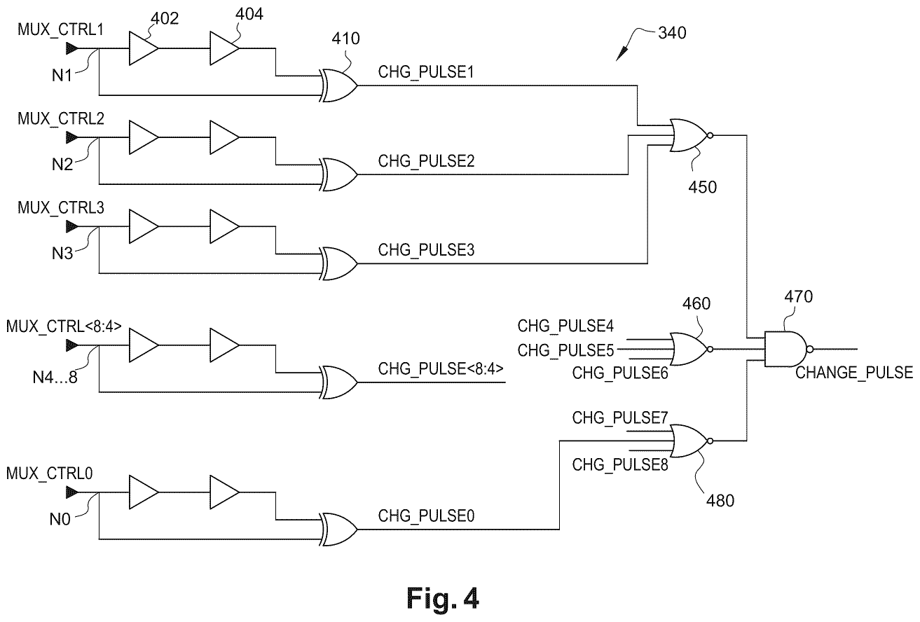

FIG. 4 shows a circuit of the block of FIG. 3 according to an embodiment. More particularly, FIG. 4 shows an example of circuit 340.

In the shown example, circuit 340 comprises nine similar branches, configured to each receive, on a different input node, one of selection control signals MUX_CTRL<8:0>.

Each of the branches comprises one or a plurality of time shift circuits 402, 404 in series between the respective input node N0, N1, N2, N3, N4, N5, N6, N7, N8 of the branch which respectively receives one of signals MUX_CTRL<8:0> and an input of a logic block 410 of the same branch. Another input of logic block 410 is looped back on the input node of its respective branch.

Each logic block 410 is configured to perform an XOR function based on the signal present on the input node of the respective branch and based on the signal having traveled through time shift circuits 402, 404. The selection control signal MUX_CTRL<8:0> present on the input node of a branch will thus be processed by the corresponding logic block 410 with its time-shifted version. This enables to detect a change having occurred on selection control signals MUX_CTRL<8:0> during the time shift, in other words during the delay, introduced by circuits 402 and 404. The number of time shift circuits 402, 404 in series in each branch may be greater than two or equal to one. The number of time shift circuits has an influence on the duration of the pulse of signal CHANGE_PULSE. Those skilled in the art may adapt this number to ensure a proper operation of circuit 310 in all conditions of use of the integrated circuit. The output of each of logic blocks 410, respectively noted CHG_PULSE<8:0>, is coupled, preferably connected, to a logic block configured to perform a NOR-type function. In the shown example, a logic block 450 is configured to perform a NOR function based on signals CHG_PULSE1, CHG_PULSE2, and CHG_PULSE3, a logic block 460 is configured to perform a NOR function based on signals CHG_PULSE4, CHG_PULSE5, and CHG_PULSE6, and a logic block 480 is configured to perform a NOR function based on signals CHG_PULSE0, CHG_PULSE7, and CHG_PULSE8.

Circuit 340 further comprises a logic block 470 configured to perform a NAND-type function based on the outputs of logic blocks 450, 460, and 480. Signal CHANGE_PULSE, which indicates whether a change has occurred on one or a plurality of selection control signals MUX_CTRL<8:0>, is generated on the output of logic block 470. In other words, logic blocks 450, 460, 470, and 480 form together an OR-type logic block which combines signals CHG_PULSE<8:0> to generate a pulse on signal CHANGE_PULSE when a change is detected.

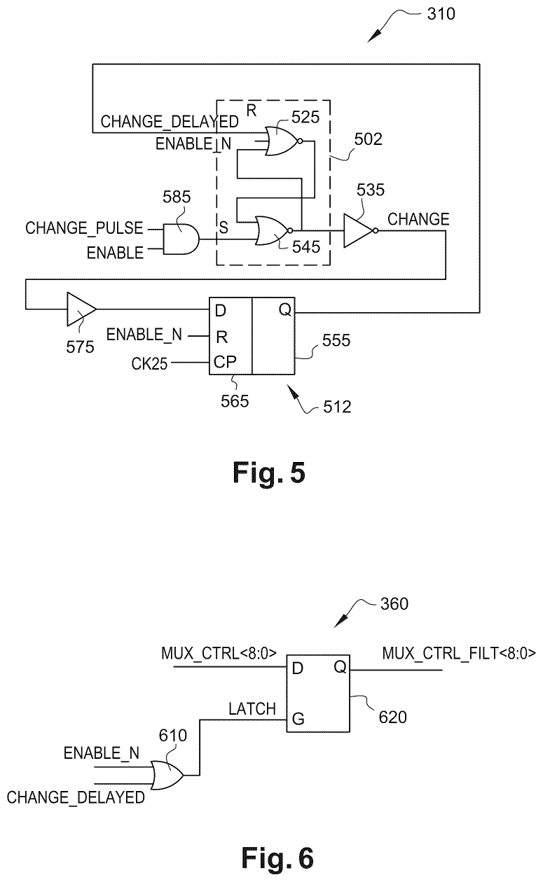

FIG. 5 shows a circuit of the block of FIG. 3 according to an embodiment. More particularly, FIG. 5 shows an embodiment of circuit 310.

In the shown example, circuit 310 comprises a logic block 585 coupled, preferably connected, to the output of block 470 of circuit 340. Logic block 585 is configured to perform an AND-type function based on an enable signal ENABLE and on signal CHANGE_PULSE. The output of logic block 585 is coupled, preferably connected, to an input, for example S, of an SR-type latch 502. In other words, when signal ENABLE is activated, the pulse of signal CHANGE_PULSE is also present on the S input. Another input, for example the R input, of latch 502 is coupled to an output of a shift register 512. An output of latch 502 is coupled to an input of shift register 512 via an inverter 535 in series with a time shift block 575 (optional). The signal at the output of inverter 535 is signal CHANGE.

In the shown example, shift register 512 is formed by two flip-flops 565, 555, for example D flip-flops, in series. Those skilled in the art may select a shift register having more than two flip-flops in series. The D input of flip-flop 565 is coupled, preferably connected, to the output of inverter 535, optionally via time shift block 575. The reset input R of flip-flop 565 is configured to receive signal ENABLE_N and its clock input CP is configured to receive the slowest clock signal, here CK25. The Q output of flip-flop 555 is coupled to the R input of latch 502.

In an example, latch 502 is formed of two cross-coupled logic gates 525, 545, for example of NOR, or possibly NAND type.

In the shown example, gate 525 comprises three inputs, the R input receiving the signal CHANGE_DELAYED originating from shift register 512, an input configured to receive an enable signal ENABLE_N and an input coupled to the output of logic gate 545. An input of logic gate 545 comprises the S input and another input of logic gate 545 is coupled to the output of logic gate 525.

In operation, when the signal on the R and S inputs are in the low state, the output of latch 502 is kept stable. If the signal on the S input is a high pulse while the signal on the R input remains low, the output signal changes and then remains held therein, including when the signal on the S input returns to a low state. Similarly, if signal CHANGE_DELAYED is a rising pulse and the signal on the S input is held in the low state, then the output signal of latch 502 changes and remains held therein, including when signal CHANGE_DELAYED switches to the low state. Thus, signal CHANGE switches to the high state when a positive pulse is present on signal CHANGE_PULSE and it switches to the low state when signal CHANGE_DELAYED switches to the high state. On the other hand, signal CHANGE_DELAYED is the image of signal CHANGE with a time shift of three rising edges of the slowest clock signal, here CK25. The time shift between signal CHANGE and CHANGE_DELAYED will thus enable switch 225 to turn on, after the clock signal has been selected and delivered at the output of selector 320, which enables it to comprise no glitches having occurred during the selection.

Time shift block 575 enables to avoid for the holding of the output of latch 502 to be deteriorated when signal CHANGE_DELAYED rises to the high state, which might generate a falling edge on signal CHANGE.

FIG. 6 shows a circuit of the block of FIG. 3 according to an embodiment. More particularly, FIG. 6 shows an embodiment of circuit 360.

In the shown example, circuit 360 comprises a single illustrated branch. Other branches, corresponding to the processing of all signals MUX_CTRL<8:0> are not shown but are similar. Circuit 360 comprises a logic block 610 configured to perform an OR-type function based on signal CHANGE_DELAYED and on enable signal ENABLE_N. Each branch comprises a latch 620. The output LATCH of logic block 610 is coupled to a control input G of each of latches 620 (LATCH). Thus, signal LATCH arrives on the G input of the latch 620 of each branch. A D input of latches 620 is configured to receive one of the respective selection control signals MUX_CTRL<8:0>. This signal MUX_CTRL<8:0> becomes signal MUX_CTRL_FILT<8:0> once propagated on the Q output of latch 620. Thus, signal LATCH, which correspond to the propagated signal CHANGE_DELAYED, controls the propagation of the raw selection control signals MUX_CTRL<8:0> before they have propagated to selector 320. Signal LATCH is in a high level preferably only when the clock signal CK_DIG_RAW at the output of selector 320 is in the low state, otherwise it is possible for a parasitic pulse to be present.

In an example, latch 620 is replaced with a D flip-flop (which basically consists of two latches in series) which is more secure but which occupies twice more room than a simple latch.

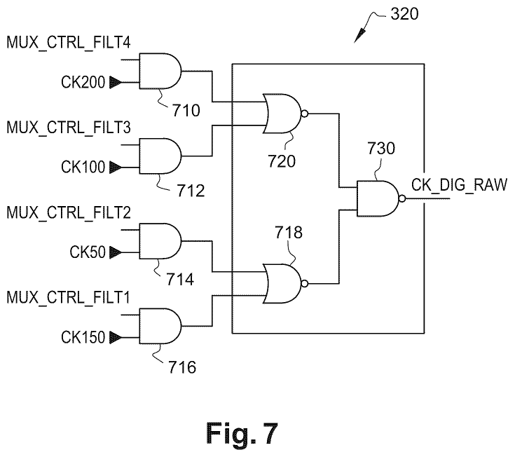

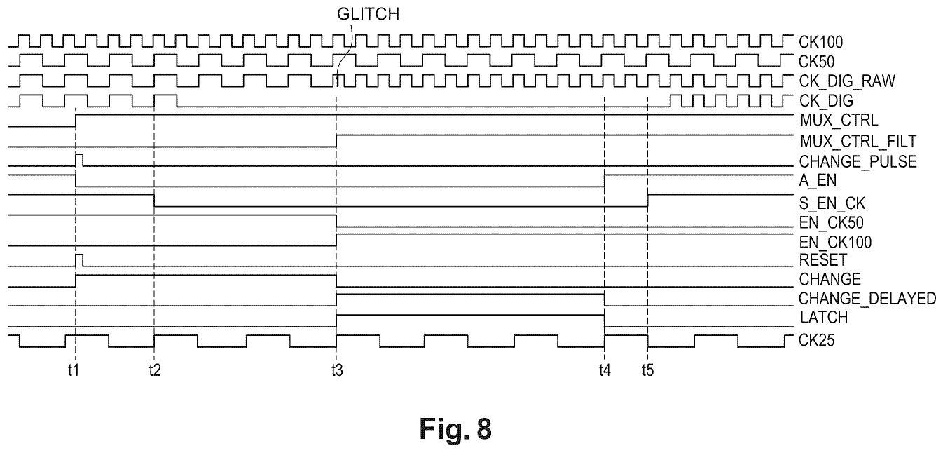

FIG. 7 shows a circuit of the block of FIG. 3 according to an embodiment. More particularly, FIG. 7 illustrates an embodiment of selector 320.

In the shown example, circuit 320 comprises four logic blocks 710, 712, 714, 716 configured to perform an OR-type function respectively based on signals MUX_CTRL_FILT4, CK200; MUX_CTRL_FILT3, CK100; MUX_CTRL_FILT2, CK50; MUX_CTRL_FILT1, CK150; signal CK150 for example being a clock signal having a frequency intermediate between those of signals CK100 and CK200.

In the shown example, circuit 320 also comprises two logic blocks 718, 720 configured to perform a NOR function respectively based on the outputs of logic blocks 714, 716 and 710, 712.

Circuit 320 further comprises a logic block 730 configured to perform a NAND function based on the outputs of logic blocks 718 and 720. The combination of logic blocks 718, 720, and 730 enables to perform an OR-type logic function based on the outputs of logic blocks 710, 712, 714, and 716. The output signal of block 730 is the selected clock signal CK_DIG_RAW before its running through switch 225.

In the shown example, only four logic blocks 710, 712, 714, 716 are shown, however the architecture shown in FIG. 7 may be duplicated so that the selection of the clock signal is performed based on a higher number of available clock signals.

For a single clock signal to be selectable at once, signals MUX_CTRL_FILT<8:0> are preferably exclusive. When one of signals MUX_CTRL_FILT<8:0> is in a high level, then the clock signal present on the other input of logic block 710, 712, 714, 716 is propagated to the output of selector 320 and becomes signal CK_DIG_RAW.

FIG. 8 is a timing diagram of the operation of the block 180 of FIG. 3. More particularly, FIG. 8 shows the time variation of signals CK100, CK50, CK_DIG_RAW, CK_DIG, MUX_CTRL, MUX_CTRL_FILT, CHANGE_PULSE, A_EN,S_EN_CK, EN_CK50,EN_CK100, RESET, CHANGE, CHANGE_DELAYED, LATCH, and CK25. In the shown example, signal MUX_CTRL is the selection control signal among signals MUX_CTRL<8:0>, which controls the selection of signal CK100.

The shown example illustrates the selection and the passing from signal CK50 to signal CK100 on the node NOUT of FIG. 3.

Between a time t1 and a time t7, signals CK25, CK50, and CK100 alternate high states and low states with a duty cycle close to or equal to 50%. The frequency of CK100 is twice that of CK50 and four times that of CK25.

Between time t1 and a time t3 before time t7, the signal CK_DIG_RAW elected and propagated by selector 320 is signal CK50.

At time t1, circuit 340 detects a change in selection control signals MUX_CTRL<8:0> and signal MUX_CTRL switches from a low level to a high level, then remains stable at the high level. A pulse is then generated on signal CHANGE_PULSE, which generates the switching from the high state to the low state of signal A_EN, and a rising edge of clock signal CK25 later, at a time t2 preceding time t3, the second block 230 of switch 225 switches from the high state to the low state and interrupts the propagation of signal CK50. Output signal CK_DIG then becomes zero or stable at the low state.

At time t1, a positive pulse is sent on signal RESET, which resets the latch 502 of circuit 310 and signal CHANGE switches from the low state to the high state, then remains stable. At the end of the third rising edge of clock signal CK25 following this reset and the pulse of signal CHANGE_PULSE, that is, at time t3, signal CHANGE_DELAYED switches from the low state to the high state.

Circuit 360 blocks, between time t1 and time t3, the modification of signal MUX_CTRL. At time t3, signal LATCH and signal EN_CK100 switch from the low state to the high state, which enables to propagate selection control signal MUX_CTRL through the corresponding latch. At time t3, signal EN_CK50 switches from the high state to the low state to stop the selection of signal CK50. Clock signal CK100 is selected by selector 320 and forms signal CK_DIG_RAW. However, this clock signal change has caused a glitch (designated as GLITCH in the timing diagram). However, switch 225 being off at this stage, the glitch is not propagated.

At time t3, SR latch 502 is reset by the rising of signal CHANGE_DELAYED and signal CHANGE switches from the high state to the low state. The state of signal CHANGE propagates on the state of signal CHANGE_DELAYED at the third rising edge of clock signal CK25 following t3 at a time t4.

At time t4, signal CHANGE_DELAYED switches from the high state to the low state and accordingly signal LATCH does the same. Signal A_EN switches from the low state to the high state and, after two next rising edges of clock signal CK100, at a time t5, signal S_EN_CK switches from the low state to the high state. The second block 230 of switch 225 then implements the propagation of signal CK100 on the output node NOUT of switch 225 after the next rising edge of signal CK100 and signal CK_DIG then becomes signal CK100.

Various embodiments and variants have been described. Those skilled in the art will understand that certain features of these various embodiments and variants may be combined, and other variants will occur to those skilled in the art. In particular, the number of flip-flops in series of the block 202 of the switches may be greater than two and the type of the flip-flops of this block may be different from D flip-flops.

In another example, shift register 512 may be replaced with a reclocking cell of the same type as block 202. This enables to decrease the risk of jitter linked to the potential desynchronization of the selection control signals and the clock signal used as a clock input of the shift register.

Generally, the example of circuit 310 shows an example for generating a time shift between turning off of switch 225 and the selection of the new clock signal, then also between the selection of the clock signal and turning on of switch 225. Those skilled in the art may implement their knowledge to perform such a time shift with other circuit architectures, provided for the time shift to be of at least three, preferably four, rising edges of a clock signal (CK25) having a frequency twice lower than the slowest clock signal to be selected (CK50).

An example of a selector 320 is disclosed in FIG. 7, however, those skilled in the art may implement their knowledge to implement a circuit for selecting one signal out of a plurality of signals based on selection control signals. Such a circuit is for example a multiplexer (MUX).

Finally, the practical implementation of the described embodiments and variants is within the abilities of those skilled in the art based on the functional indications given hereabove. In particular, regarding switches 225, they may for example only comprise second block 230, without first block 202, provided for the clock signal to no longer be propagated on output node NOUT only when the clock signal is in the low state to avoid glitches, and provided for the enable signal S_EN_CK of second block 230 to be synchronous with the clock signal to be stopped or to be propagated.

The supply circuit 180 such as described hereabove may be integrated in a low-power microcontroller, for example.

1. A circuit for supplying a clock signal comprising:
a selector to select one signal out of a plurality of clock signal;
a switch between the selector and a node for outputting a selected clock signal;
wherein the circuit is configured so that an application of a selection control signal for selecting one of the clock signals causes, in order, the turning off of the switch, the selection of the one signal out of a plurality of clock signal via the selector, and the turning on of the switch.

2. The circuit of claim 1, wherein the circuit is further configured to turn off the switch when a change in the selection control signal is detected.

3. The circuit of claim 2, wherein the circuit is further configured to select the signal after a first delay, of at least two rising edges of a shift signal, following the detection of the change.

4. The circuit of claim 3, wherein the circuit is further configured to turn on the switch after a second delay, of at least two rising edges of the shift signal, following the selection.

5. The circuit of claim 2, wherein the circuit is further configured to generate, with a first circuit, a first signal when the change is detected.

6. The circuit of claim 3, wherein the circuit is further configured to generate, with a second circuit, a second signal, originating from a first signal, and time-shifted by the first delay.

7. The circuit of claim 6, wherein the second circuit comprises:
an SR-type latch having an output coupled to an inverter which is in series with an input of a shift register comprising at least two stages and/or a delay cell;
wherein a second signal being generated on an output of the shift register; and
a first input of the SR-type latch being configured to receive the first signal and a second input of the SR-type latch being configured to receive the second signal.

8. The circuit of claim 1, the circuit comprising a third circuit configured to authorize a propagation of the selection control signal to the signal selector according to an output of a first logic block capable of performing a NOR function based on a signal present at the output of an inverter and on a second signal.

9. The circuit of claim 8, the third circuit comprising one latch per control signal forming the selection control signal, each latch having:
a gate input coupled to the output of the first logic bloc;
a data input configured to receive a corresponding control signal; and
an output coupled to the signal selector.

10. The circuit of claims 3, wherein the shift signal is a clock signal having a frequency smaller than or equal to that of the signal, among the plurality of clock signals, having the smallest frequency.

11. The circuit of claim 8, wherein the switch comprises a first block comprising:
a clock input coupled to the selector;
a first enable input coupled to the output of the first logic block;
an output coupled to a second enable input of a second block of the switch; and
an output of the second block of the switch being coupled to the output node and a clock input of the second block being coupled to an output of the selector.

12. The circuit of claim 8, wherein the switch is configured to be off when the output of the first logic block is at a low level.

13. The circuit of claim 1, wherein the switch is configured to be on when the output of the first logic block is at a high level, the selected clock signal then also being present on the output node.

14. The circuit of claim 11, wherein the first block of the switch comprises a first and a second flop-flops in series, the clock input of the first block being a clock input of the first flip-flop and the output of the second flip-flop being coupled to the second enable input of the second block.

15. A method of operation of a circuit for supplying a clock signal, the method comprising, as a result of the application of a selection control signal for selecting a signal, successively:
turning off of a switch coupling a selector of one clock signal out of a plurality and an output nod;
selecting the signal via the selector; and
turning on of the switch.

16. The method of claim 15 further comprising turning off the switch when a change in the selection control signal is detected.

17. The method of claim 16 further comprising selecting the signal after a first delay, of at least two rising edges of a shift signal, following detection of the change.

18. The method of claim 17 further comprising turning on the switch after a second delay, of at least two rising edges of the shift signal, following selecting the signal via the selector.

19. The method of 16 further comprising generating, with a first circuit, a first signal when the change is detected.

20. A microcontroller comprising the circuit for supplying a clock signal of claim 1.
